(19) United States
(12) Patent Application Publication
(10) Pub. No.: US 2012/0146216 A1
(43) Pub. Date: Jun. 14, 2012

(54) SEMICONDUCTOR PACKAGE AND FABRICATION METHOD THEREOF

(75) Inventors: In Soo KANG, Cheongju-si (KR); Yong Tae Kwon, Suwon (KR); Byung Jin PARK, Chungbuk (KR)

(73) Assignee: NEPES CORPORATION, Chungcheongbuk-do (KR)

(21) Appl. No.: 13/040,008

(22) Filed: Mar. 3, 2011

(30) Foreign Application Priority Data
Dec. 9, 2010 (KR) 10-2010-125301

(51) Int. Cl. H01L 23/485; H01L 21/50; H01L 23/48; H01L 21/56

(52) U.S. Cl. 257/737; 438/127; 438/108; 257/774; 257/E23.021; 257/E21.502; 257/E21.499; 257/E23.011

(57) ABSTRACT

A semiconductor package is provided. The package includes a package substrate with a first surface and a second surface on the opposite side, and a plurality of via sets connecting vertically the first surface with the second surface, said via sets having a plurality of micro vias and filled with conductive material. The micro vias are grouped together, and the distance between micro vias in the via set is smaller than the distance between neighboring via sets.

### TECHNICAL FIELD

The present invention relates to a semiconductor package, and more particularly, to a new semiconductor package with a package substrate having via sets therein.

### BACKGROUND ART

As personal computers, portable phones, personal information terminals and electronic products have become small, light and been functionalized, data processing capacity has greatly increased. In accordance with this tendency, a wafer level chip size package has been considered as suitable technology for small sized and high speed package. Development of integration technology and new electronic devices requires enhanced semiconductor system with high performance. Semiconductor system such as SiP includes plurality of semiconductor chips and other electronic components in a single package. To efficiently fabricate semiconductor systems, various high technologies related to chip integration, metallization layout, or stacking are required.

As the size of a chip gets smaller, a semiconductor chip with fine pitch components should be required to further use a package substrate since it has a limit to be electrically connected to other device or a circuit board. Recently, a semiconductor substrate with through-via is getting increasingly used as a package substrate. Through-via is suitable for high performance and multi-functional system since it enables a semiconductor substrate to have a shortest connection therein.

However, through-via technology has to solve some technical problems that the distance between neighboring vias and via diameter should be reduced for a high integrated semiconductor chip. Thus, development of new technology for via formation and via filling has been strongly demanded.

Another technical issue relates to excessive via density in a semiconductor system. A package substrate with a lot of vias therein suffers from thermal stress between a semiconductor substrate and via filling material in fabrication process. The thermal stress leads to defects in final product and difficulties in following process. Moreover, due to a lot of vias, the package substrate has increased volume of conductive material therein, which results in deterioration of electrical and mechanical reliability of a semiconductor package.

### SUMMARY

Therefore, the present invention is directed to provide a new semiconductor package with enhanced reliability and performance.

Another object of the present invention is to provide a semiconductor package with a new package substrate having a via set therein.

Still another object of the present invention is to provide a semiconductor packaging process with enhanced reliability and effectiveness.

In accordance with an aspect of the present invention, the present invention provides a semiconductor package, comprising: a package substrate with a first surface and a second surface on the opposite side, and a plurality of via sets connecting vertically the first surface with the second surface, said via sets having a plurality of micro vias and filled with conductive material, wherein the micro vias are grouped together, and the distance between micro vias in the via set is smaller than the distance between neighboring via sets.

In accordance with another aspect of the present invention, the present invention provides a semiconductor package, comprising: a package substrate with a first surface and a second surface on the opposite side, said package having a via set connecting vertically the first surface with the second surface, wherein the via set has a plurality of micro vias and are filled with conductive material, a first dielectric layer on the first surface of the package substrate, said first dielectric layer exposing an end of the via set, a first redistribution layer on the first dielectric layer and electrically connected to the end of via set, a second dielectric layer on the second surface of the package substrate, said second dielectric layer exposing the other end of the via set, a second redistribution layer on the second dielectric layer and electrically connected to the other end of via set, a semiconductor chip mounted over the package substrate and electrically connected to the first redistribution layer, a molding layer on the first dielectric layer and the first redistribution layer and covering the semiconductor chip, and a bump electrically connected to the second redistribution layer.

The micro vias are grouped together, and the distance between micro vias in the via set is smaller than the distance between neighboring via sets.

The micro vias in the via set are collectively connected to an end of the first redistribution layer or the second redistribution layer.

The molding layer covers the upper surface of the semiconductor chip and is formed in the same length as that of the package substrate.

In accordance with further another aspect of the present invention, the present invention provides a method for fabricating a semiconductor package, comprising: preparing a package substrate with a first surface and a second surface on the opposite side, forming a via set vertically perforating the package substrate, said via set having a plurality of micro vias, filling conductive material into the via set, performing a back side process on the second surface; a) forming a second dielectric layer on the second surface to expose the via set, b) forming a second redistribution layer on the second dielectric layer, bonding a carrier on the second surface of the package substrate, grinding the first surface of the package substrate to expose the via set, performing a front side process on the first surface; a) forming a first dielectric layer on the first surface to expose the via set, b) forming a first redistribution layer on the first dielectric layer, mounting a semiconductor chip over the first surface to be electrically connected to the first redistribution layer, forming a molding layer to cover semiconductor chip, removing the carrier from the package substrate, and forming a bump to be electrically connected to the second redistribution layer at the second surface.

In accordance with still another aspect of the present invention, the present invention provides a method for fabricating a semiconductor package, comprising: preparing a package substrate with a first surface and a second surface on the opposite side, forming a via set vertically perforating the package substrate, said via set having a plurality of micro vias, filling conductive material into the via set, performing a front side process on the first surface; a) forming a first dielectric layer on the first surface to expose the via set, b) forming a first redistribution layer on the first dielectric layer, mounting a semiconductor chip over the first surface to be electrically connected to the first redistribution layer, forming a molding layer to cover semiconductor chip, bonding a carrier on the first surface of the package substrate, grinding the second surface of the package substrate to expose the via set, performing a back side process on the second surface; a) forming a second dielectric layer on the second surface to expose the via set, b) forming a second redistribution layer on the second dielectric layer, forming a bump to be electrically connected to the second redistribution layer at the second surface, and removing the carrier from the package substrate.

According to the present invention, by minimizing the volume of the conductive material filled in the vertical through hole of a package substrate, the present invention can relieve the stress between the different materials in packaging process, and enhances the reliability of wafer level molding and wafer level packaging process.

Moreover, the present invention allows high degree of freedom of material and layout in semiconductor package such that excellent devices can be fabricated in wafer level metallization and molding process.

Furthermore, the present invention improves durability and electrical performance of a semiconductor package, and allows cost effectiveness and high yield in semiconductor packaging process.

### DESCRIPTION OF DRAWINGS

The above and other features and advantages of the present invention will become more apparent to those of ordinary skill in the art by describing in detail preferred embodiments thereof with reference to the attached drawings in which:

FIG. 1 shows a sectional view of a semiconductor package in accordance with a preferred embodiment of the present invention.

FIG. 2 is a schematic sectional view of a package substrate.

FIG. 3 is a plan view of a part of the package substrate.

FIG. 4 is a plan view of an example of a via set.

FIG. 5 is a plan view of another example of a via set.

FIG. 6 is a plan view of an example of a redistribution layer connected to the via set.

FIGS. 7 to 10 are sectional views showing steps of a fabrication process in accordance with one embodiment of the present invention.

FIGS. 11 to 14 are sectional views showing steps of a fabrication process in accordance with another embodiment of the present invention.

### MODE FOR INVENTION

The present invention will now be described more fully hereinafter with reference to the accompanying drawings, in which preferred embodiments of the invention are shown. The present invention relates to a highly integrated and multi functional semiconductor system package with semiconductor chips, integrated devices, and/or passive devices. The system package may include a semiconductor substrate (for example, a silicon wafer) as a package substrate for mounting electronic devices thereon, instead of a printed circuit board (PCB). A silicon wafer is advantageous for packaging process in wafer level.

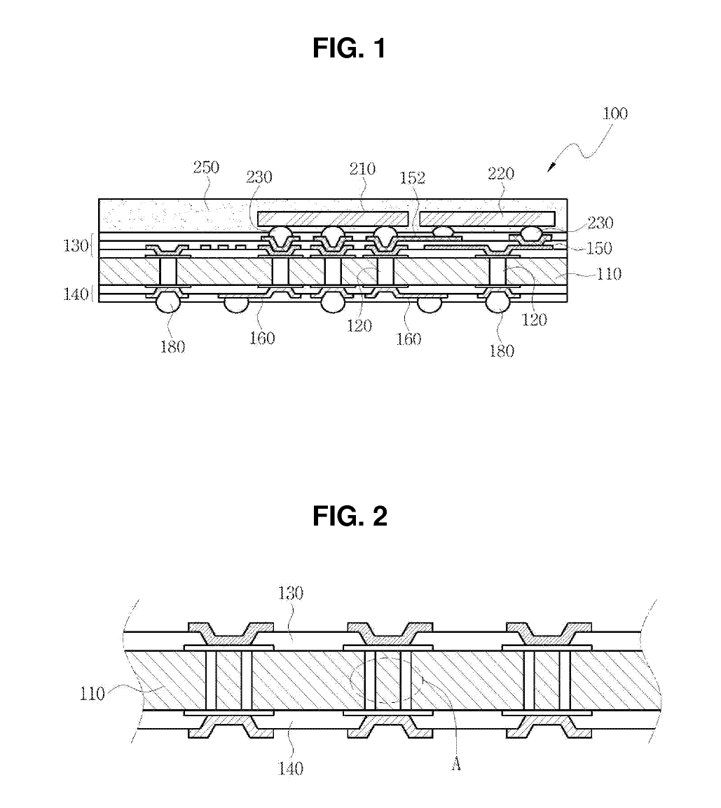

FIG. 1 shows a sectional view of a semiconductor package (100) in accordance with the present invention. A package substrate (110) has a first surface, a second surface on the opposite side, and a plurality of via sets (120) vertically formed therein.

The via set (120) connects the first surface (for example, upper surface) of the package substrate (110) with the second surface (for example, lower surface). The via set, as shown in ‘A’ part of FIG. 2, includes at least two through holes which penetrate the inner part of the package substrate and are exposed to a first dielectric layer (130) on the first surface and a second dielectric layer (140) on the second surface. The via sets are filled with conductive material, such as Cu, and the upper and the lower ends of the via set may be electrically connected to a conductive pad or an electrode pad at the exposed part from the first dielectric layer or the second dielectric layer.

The first dielectric layer (130) on the first surface of the package substrate expose one end of the via set and may consist of multiple layers. A first redistribution layer (150) is form on the first dielectric layer and is electrically connected to the one end of the via set. When the first dielectric layer has multiple layers, the first redistribution layer may include more than one layer (as shown in FIG. 1: 150, 152).

The second dielectric layer (140) on the second surface of the package substrate expose the other end of the via set and may consist of multiple layers. A second redistribution layer (160) is form on the second dielectric layer and is electrically connected to the other end of the via set. When the second dielectric layer has multiple layers, the second redistribution layer may include more than one layer.

Adjacent to the first redistribution layer or the second redistribution layer, an integrated passive device (IPD) may be formed on the first surface or the second surface of the package substrate.

Semiconductor chips (210, 220) are mounted over the first surface of the package substrate and may be electrically connected to the first redistribution layer (or the electrode pad connected to the via set). The semiconductor chip can be, for example, memory chip, IC chip, IPD, or other non-memory functional semiconductor device. The semiconductor chip and the first redistribution layer (or the electrode pad) may be electrically connected to each other via micro bump (230). Additionally, another semiconductor chip (not shown) may be mounted under the second surface of the package substrate and electrically connected to the second redistribution layer (or an electrode pad connected to the via set).

Over the first surface of the package substrate, a molding layer (250) is formed on the first dielectric layer to cover the semiconductor chips. The molding layer can be formed in wafer level process after thin film layers (such as dielectric layers and redistribution layers) and semiconductor chips are stacked over the package substrate. Then, in the continued sawing process, the molding layer can be divided into individual package units. As a result, the horizontal length of the molding layer becomes the same as that of the package substrate, and the molding layer exists only on the upper part of the package substrate, except for side or under part. The molding layer may be grinded in further process to expose the upper surface of the semiconductor chip for better thermal emission.

Under the second surface of the package substrate, a bump (180) contacts with the second redistribution layer or and an electrode pad connected to the lower end of the via set.

The present invention can make it possible to realize system-in-package in wafer level process. Specifically, all the steps such as forming via holes in the package substrate, forming redistribution layer and dielectric layer, forming thin film passive device, mounting semiconductor chip and IPD, and forming molding layer can be continuously processed in wafer level. Moreover, since a silicon wafer which is of the same material as a semiconductor chip to be mounted is used as a package substrate, any defect due to CTE (Coefficient of Thermal Expansion) difference between a chip and a substrate during packaging process can be remarkably reduced.

In the present application, the via set penetrates from the upper surface of the package substrate to the lower surface and functions substantially as an electrical connection between a semiconductor chip and an exterior bump. Especially, the via set has small vias in a group (grouped vias), not a single via with relatively large diameter. Consequently, thermal or mechanical stress in the package substrate due to hetero material (such as Cu) filled in the via set can be relieved. Accordingly, the system elements such as dielectric layers, redistribution layers, or semiconductor chips can be formed stably on the substrate, without considering excessive manufacturing tolerance. Thus, optimization of system in package can be realized. Furthermore, since physical defects or stresses in the a package substrate due to formation of a single large via can be reduced, the durability of the final package will be enhanced.

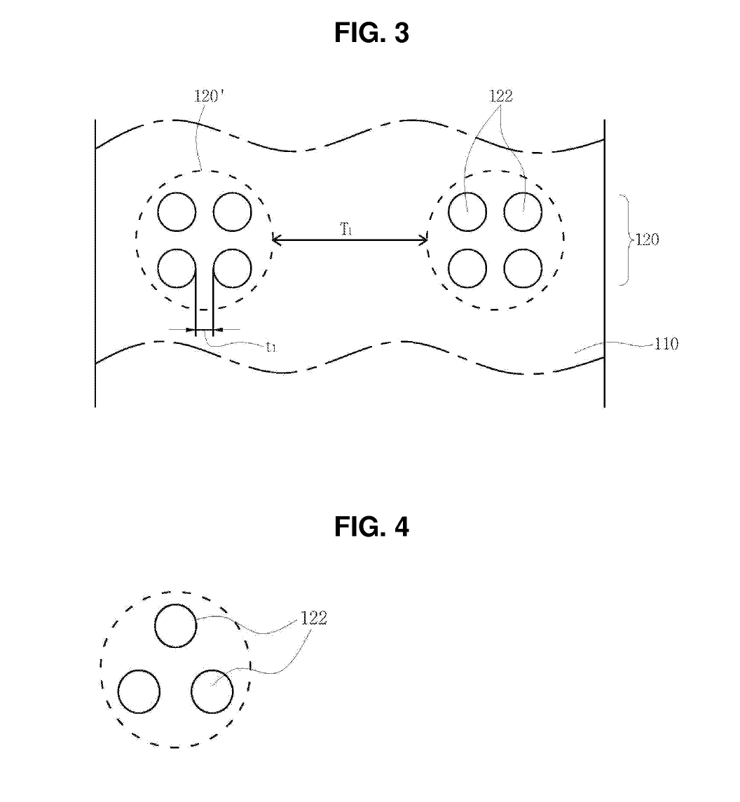

In accordance with a semiconductor package of the present invention, as shown in FIG. 2 and FIG. 3, the via set (120) in the package substrate includes micro vias (122) which are adjacent to one another and form a group. The distance (t1) between micro vias in the via set is smaller than the distance (T1) between the neighboring via sets. In comparison with micro via, for better understanding, a single via (120′) with large diameter is expressed in a dotted line in FIG. 3.

It is preferable that the total area of the via set (120) consisting of micro vias (122) is smaller than that of the single via (120′). Since the diameter of micro via is small and the neighboring vias are distantly arranged, the volume of the via set becomes remarkably reduced, compared to that of the single via. As a result, the amount of conductive material to be filled in the via set is also reduced. Consequently, the thermal and physical stress between the package substrate and the filled material in the via set will be decreased. Furthermore, the process of filling the vertical hole in the package substrate will be easier.

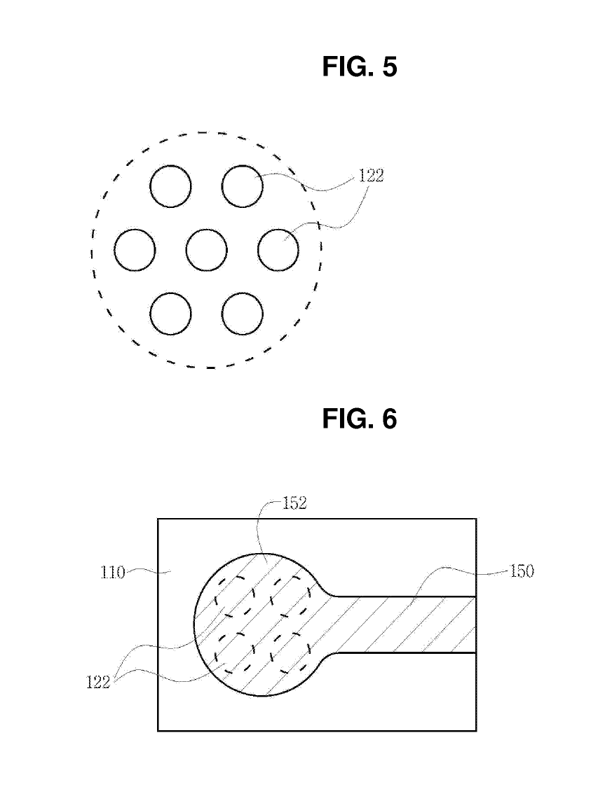

In the present invention, the via set vertically passing through the package substrate consists of at least two micro vias, and a plurality of vias (122) may be grouped together, as shown in FIG. 4 and FIG. 5.

Preferably, the grouped micro vias constitute a single electrical unit. For this end, in a semiconductor package of the present invention, the micro vias of the via set are collectively connected to an end (152) of a first redistribution layer (150) (or a second redistribution layer), as shown in FIG. 6. That is, the redistribution layer is electrically connected to all the micro vias in the via set, not to an individual micro via or a few vias in the via set. For better electrical connection, at least one electrode pad may be interposed between the via set and the redistribution layer.

In this manner, by reducing the volume and the area of the conductive material filled in the vertical through hole, the present invention can relieve the stress between the different materials in packaging process, and result in time saving and cost effectiveness in the process of filling the vertical through hole. The package substrate with via sets therein may be effectively applied to a high performance device required to have a large number of electrical connections and terminals.

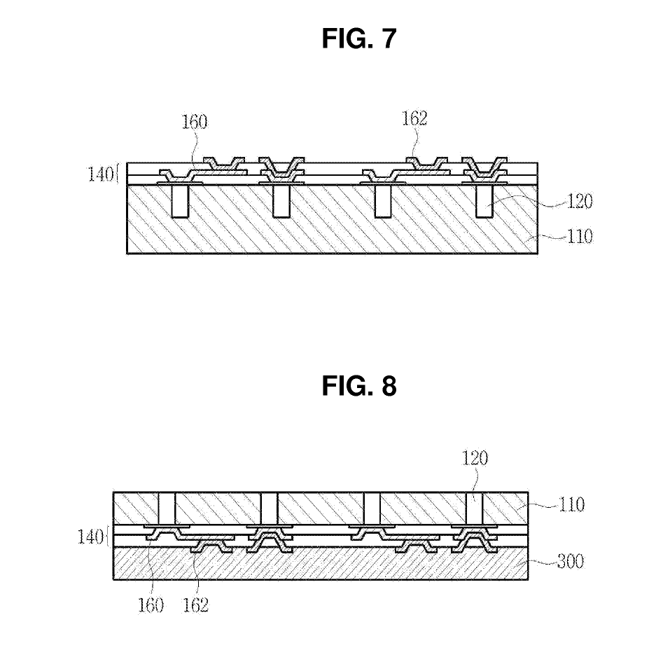

The semiconductor package of the present invention can be fabricated in two different processes, according to the order of via set formation, front side process, back side process, carrier bonding, semiconductor chip mounting, and molding layer formation. Referring to FIGS. 7 to 10, the fabrication process in accordance with a first embodiment of the present invention will be described.

Firstly, a package substrate (110) is prepared. The substrate (110) has a first surface and a second surface in the opposite side. The package substrate is partially etched to form a plurality of via sets (120). The via sets can be formed by physical method such as laser etching and RIE, or chemical method such as wet etching. Conductive material is filled up in the via set by such as electroplating. The via set is necessarily to completely perforate the package substrate, and can be formed in predetermined depth considering the thickness of the final package substrate.

Next, a back side process is performed on the second surface of the package substrate. A second dielectric layer (140) is formed on the second surface to expose the via set, and a second redistribution layer (160) is formed on the second dielectric layer. Before the formation of the second dielectric layer, an electrode pad can be formed to electrically connect to one end of the via set. When at least two second dielectric layer are formed, the second redistribution layer may include more than one layer. FIG. 7 shows the package substrate after the back side process.

Next, after boding a carrier (300) on the second surface of the package substrate, the first surface of the package substrate is grinded to expose the other end of the via set (120) at the first surface (FIG. 8).

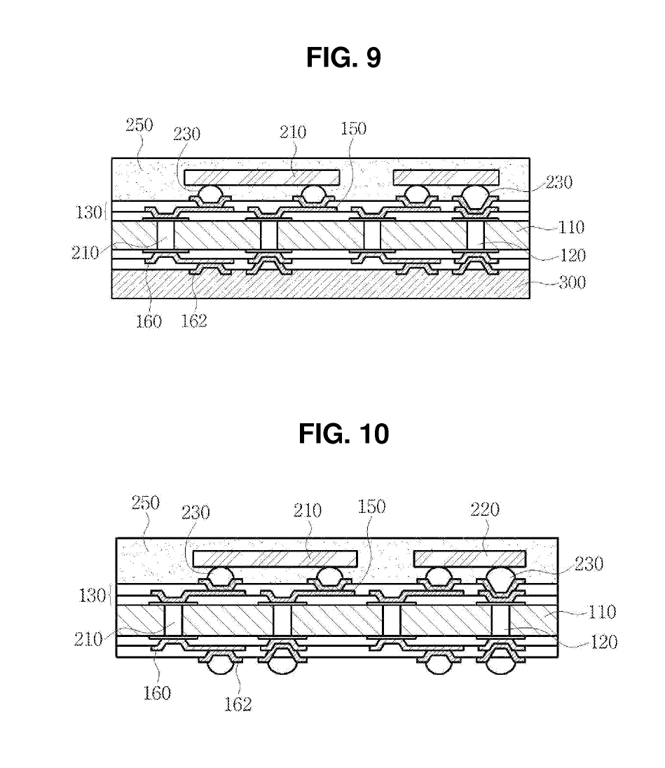

Next, as shown in FIG. 9, a front side process is performed on the first surface of the package substrate. A first dielectric layer (130) is formed on the first surface to expose the via set, and a first redistribution layer (150) is formed on the first dielectric layer. Before the formation of the first dielectric layer, an electrode pad can be formed to electrically connect to the other end of the via set. When at least two first dielectric layer are formed, the first redistribution layer may include more than one layer. At least one semiconductor chip (210) is mounted over the first surface to be electrically connected to the first redistribution layer, via flip chip bonding. Then, a molding layer (250) is formed on the first dielectric layer and the first redistribution layer to cover the semiconductor chip. Preferably, the molding layer may be formed in a wafer level in view of reliability and yield of the fabrication process. Finally, as shown in FIG. 10, the carrier is removed from the package substrate, and bumps (180) are formed to be electrically connected to the second redistribution layer on the second surface.

In this first embodiment of the present invention, after the back side process is firstly performed and a carrier is bonded, semiconductor chip mounting and molding process is followed.

Now, the fabrication process in accordance with a second embodiment of the present invention will be described. In this embodiment, the front side process, semiconductor chip mounting and wafer level molding process are performed prior to the back side process.

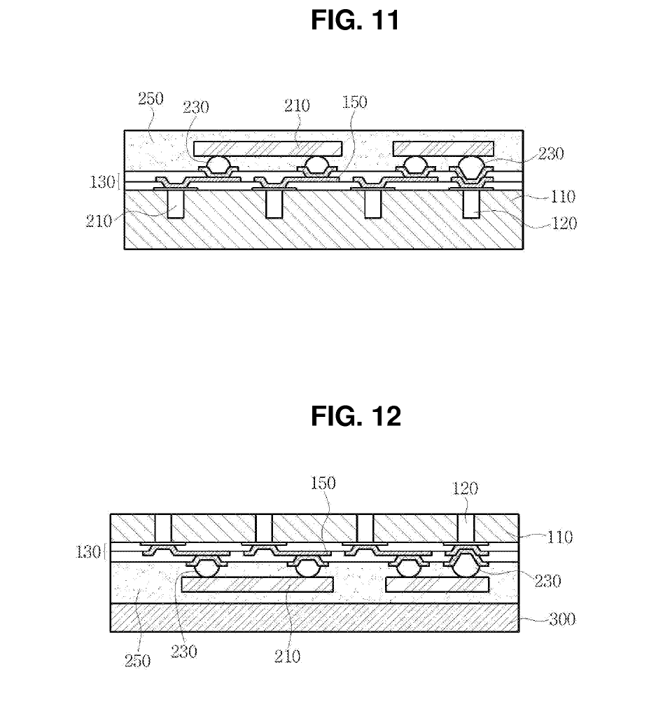

Firstly, as shown in FIG. 11, a plurality of via sets (120) is formed in a package substrate (110) and conductive material is filled up in the via set. During the front side process, a first dielectric layer (130) and a first redistribution layer (150) are formed on the first surface of the package substrate. Then, a semiconductor chip (210) is mounted over the package substrate to be electrically connected the first redistribution layer, and a molding layer (250) is formed in wafer level to cover the semiconductor chip.

In wafer level process, excessive via density in a package substrate makes worse the thermal stress between the molding layer and the package substrate such that the following processes may be difficult to be continued, and durability of a final product and reliability of a wafer level process may be deteriorated. The via set according to the present invention reduces the stress due to excessive via density and resultantly enhances the reliability of wafer level molding and wafer level packaging process.

Next, as shown in FIG. 12, after boding a carrier (300) on the first surface of the package substrate, the second surface of the package substrate is grinded to expose the via set (120) at the second surface.

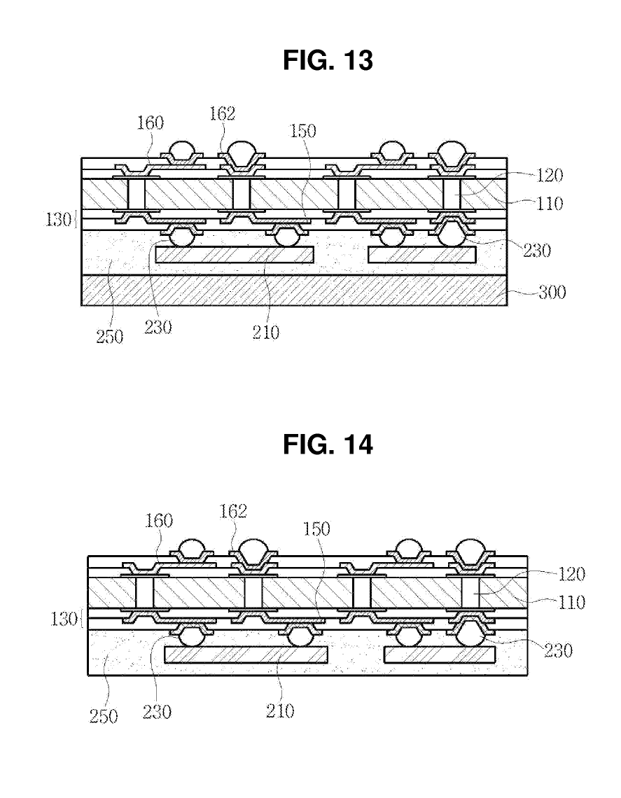

In the next step, during the back side process, a second dielectric layer (140) and a second redistribution layer (160) are formed on the second surface of the package substrate. Next, bumps (180) are formed to be electrically connected to the second redistribution layer at the second surface (FIG. 13), and finally the carrier is removed from the package substrate. In the above embodiments, the semiconductor chip may be mounted on the substrate by die attaching and be wire-bonded to the redistribution layer, instead of flip chip bonding.

Micro vias of the via set are preferable to be collectively connected to an end of the first redistribution layer or the second redistribution layer. Micro vias of the via set are also preferable to be formed simultaneously in a single process. Also, all the micro vias can be filled simultaneously with conductive material.

The above embodiments, for convenience's sake, describe a single package unit.

However, multi packages can be fabricated simultaneously in wafer level, and be divided into individual package units after bump formation and carrier removal.

The invention has been described using preferred exemplary embodiments. However, it is to be understood that the scope of the invention is not limited to the disclosed embodiments.

On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

1. A semiconductor package, comprising:
a package substrate with a first surface and a second surface on the opposite side, said package having a via set connecting vertically the first surface with the second surface, wherein the via set has a plurality of micro vias and are filled with a conductive material,
a first dielectric layer on the first surface of the package substrate, said first dielectric layer exposing an end of the via set,
a first redistribution layer on the first dielectric layer and electrically connected to the end of via set,
a second dielectric layer on the second surface of the package substrate, said second dielectric layer exposing the other end of the via set,
a second redistribution layer on the second dielectric layer and electrically connected to the other end of via set,
a semiconductor chip mounted over the package substrate and electrically connected to the first redistribution layer,
a molding layer on the first dielectric layer and the first redistribution layer and covering the semiconductor chip, and
a bump electrically connected to the second redistribution layer.

2. The semiconductor package of claim 1, wherein the micro vias are grouped together, and the distance between micro vias in the via set is smaller than the distance between neighboring via sets.

3. The semiconductor package of claim 1, wherein the micro vias in the via set are collectively connected to an end of the first redistribution layer or the second redistribution layer.

4. The semiconductor package of claim 1, wherein the molding layer covers the upper surface of the semiconductor chip and is formed in the same length as that of the package substrate.

5. The semiconductor package of claim 1, wherein the semiconductor chip is connected to the first redistribution layer by flip chip bonding.

6. A method for fabricating a semiconductor package, the method comprising:
preparing a package substrate with a first surface and a second surface on the opposite side,
forming a via set vertically perforating the package substrate, said via set having a plurality of micro vias,
filling a conductive material into the via set,
performing a back side process on the second surface the back side process comprising:
a) forming a second dielectric layer on the second surface to expose the via set,
b) forming a second redistribution layer on the second dielectric layer,
bonding a carrier on the second surface of the package substrate,
grinding the first surface of the package substrate to expose the via set,
performing a front side process on the first surface, the front side process comprising:
a) forming a first dielectric layer on the first surface to expose the via set,
b) forming a first redistribution layer on the first dielectric layer,
mounting a semiconductor chip over the first surface to be electrically connected to the first redistribution layer,
forming a molding layer to cover the semiconductor chip,
removing the carrier from the package substrate, and
forming a bump to be electrically connected to the second redistribution layer at the second surface.

7. A method for fabricating a semiconductor package, the method comprising:
preparing a package substrate with a first surface and a second surface on the opposite side,
forming a via set vertically perforating the package substrate, said via set having a plurality of micro vias,
filling a conductive material into the via set,
performing a front side process on the first surface, the front side process comprising:
a) forming a first dielectric layer on the first surface to expose the via set,
b) forming a first redistribution layer on the first dielectric layer,
mounting a semiconductor chip over the first surface to be electrically connected to the first redistribution layer,
forming a molding layer to cover the semiconductor chip,
bonding a carrier on the first surface of the package substrate,
grinding the second surface of the package substrate to expose the via set,
performing a back side process on the second surface, the back side process comprising:
a) forming a second dielectric layer on the second surface to expose the via set,
b) forming a second redistribution layer on the second dielectric layer,
forming a bump to be electrically connected to the second redistribution layer at the second surface, and
removing the carrier from the package substrate.

8. The method of claim 6, wherein the semiconductor chip is connected to the first redistribution layer by flip chip bonding.

9. The method of claim 6, wherein the micro vias in the via set are collectively connected to an end of the first redistribution layer or the second redistribution layer.

10. The method of claim 6, wherein the molding layer covers the upper surface of the semiconductor chip and is formed in the same length as that of the package substrate.

11. A package substrate, comprising:
a package substrate with a first surface and a second surface on the opposite side, and
a plurality of via sets connecting vertically the first surface with the second surface, said via sets having a plurality of micro vias and filled with a conductive material,
wherein the micro vias are grouped together, and the distance between micro vias in the via set is smaller than the distance between neighboring via sets.

12. The method of claim 7, wherein the semiconductor chip is connected to the first redistribution layer by flip chip bonding.

13. The method of claim 7, wherein the micro vias in the via set are collectively connected to an end of the first redistribution layer or the second redistribution layer.

14. The method of claim 7, wherein the molding layer covers the upper surface of the semiconductor chip and is formed in the same length as that of the package substrate.
